(19) United States
(12) Patent Application Publication
(10) Pub. No.: US 2026/0236463 A1
(43) Pub. Date: Aug. 13, 2026

(54) ADAPTIVE DATA RETRIEVAL USING AGENTIC PROMPT PROCESSING UNITS

(71) Applicant: Cisco Technology, Inc., San Jose, CA (US)

(72) Inventors: Marcelo Yannuzzi, Nuvilly (CH); Arash Salarian, Chardonne (CH); Jean Andrei Diaconu, Gaillard (FR); Hervé Muyal, Gland, Vaud (CH)

(73) Assignee: Cisco Technology, Inc., San Jose, CA (US)

(21) Appl. No.: 19/347,990

(22) Filed: Oct. 2, 2025

Related U.S. Application Data
(60) Provisional application No. 63/757,454, filed on Feb. 12, 2025.

(51) Int. Cl. G06F 16/2452

(52) U.S. Cl. CPC G06F 16/24524

(57) ABSTRACT

In one implementation, a device obtains a request for a generative artificial intelligence-based system to perform a task. The device formulates a primary data retrieval plan comprising a set of one or more data retrievers that the generative artificial intelligence-based system is to use to perform a task. The device identifies an issue experienced by the generative artificial intelligence-based system when performing the task in accordance with the primary data retrieval plan. The device causes, based on the issue, the generative artificial intelligence-based system to switch to an alternative data retrieval plan comprising a different set of one or more data retrievers.

### RELATED APPLICATION

This application claims priority to U.S. Prov. Appl. Ser. No. 63/757,454, filed Feb. 12, 2025, entitled ADAPTIVE DATA RETRIEVAL USING AGENTIC PROMPT PROCESSING UNITS, by Yannuzzi, et al., the contents of which are incorporated herein by reference.

### TECHNICAL FIELD

The present disclosure relates generally to computer networks, and, more particularly, to adaptive data retrieval using agentic prompt processing units (PPUs).

### BACKGROUND

The recent breakthroughs in large language models (LLMs) represent new opportunities across a wide spectrum of industries. More specifically, the ability of new models to follow instructions now allows for interactions with tools that can perform tasks such as searching the web, executing code, etc. In addition, agents can be developed to perform complex tasks and workflows by chaining multiple calls to one or more LLMs.

For example, an Agentic Data Retrieval (ADR) process may receive the prompt, either by working in tandem with the one or more LLMs or by being placed on the path toward the one or more LLMs. However, leveraging an ADR process is not without challenges. Even if an ADR process could correctly identify the data required by a prompt and map such information to a set of candidate functions to be called in order to retrieve the data, there are still several problems that may need to be solved before a prompt can be successfully completed.

For instance, the same data might be stored in multiple systems, often with varying levels of quality and complexity to retrieve the desired data. Moreover, once a plan is defined, the mere nature of an ADR process implies that its execution is not deterministic. In addition, attempts to retrieve data may fail (e.g., the data might not be available anymore, or the permissions and/or entitlements of a user, a group of users, or a service account associated to a retrieval function might have changed). Consequently, once a plan is defined, its execution is not guaranteed.

### BRIEF DESCRIPTION OF THE DRAWINGS

The implementations herein may be better understood by referring to the following description in conjunction with the accompanying drawings in which like reference numerals indicate identically or functionally similar elements, of which:

FIG. 1 illustrates an example computing system;

FIG. 2 illustrates an example network device/node;

FIG. 3 illustrates an example of an architecture for sending prompts to a remote language model;

FIG. 4 illustrates an example of an architecture utilizing prompt processing units;

FIG. 5 illustrates an example of an architecture implementing an adaptive data retrieval technique using agentic prompt processing units;

FIG. 6 illustrates an example of a procedure incorporating some of the main interactions between agentic request extraction and planner, plan criticizer, context collection and execution components; and

FIG. 7 illustrates an example simplified procedure for using prompt processing units for adaptive data retrieval, in accordance with one or more implementations described herein.

### DESCRIPTION OF EXAMPLE IMPLEMENTATIONS

### Overview

According to one or more implementations of the disclosure, a device obtains a request for a generative artificial intelligence-based system to perform a task. The device formulates a primary data retrieval plan comprising a set of one or more data retrievers that the generative artificial intelligence-based system is to use to perform a task. The device identifies an issue experienced by the generative artificial intelligence-based system when performing the task in accordance with the primary data retrieval plan. The device causes, based on the issue, the generative artificial intelligence-based system to switch to an alternative data retrieval plan comprising a different set of one or more data retrievers.

Other implementations are described below, and this overview is not meant to limit the scope of the present disclosure.

### Description

A computer network is a geographically distributed collection of nodes interconnected by communication links and segments for transporting data between end nodes, such as personal computers and workstations, or other devices, such as sensors, etc. Many types of networks are available, ranging from local area networks (LANs) to wide area networks (WANs). LANs typically connect the nodes over dedicated private communications links located in the same general physical location, such as a building or campus. WANs, on the other hand, typically connect geographically dispersed nodes over long-distance communications links, such as common carrier telephone lines, optical lightpaths, synchronous optical networks (SONET), synchronous digital hierarchy (SDH) links, and others. The Internet is an example of a WAN that connects disparate networks throughout the world, providing global communication between nodes on various networks. Other types of networks, such as field area networks (FANs), neighborhood area networks (NANs), personal area networks (PANs), enterprise networks, etc. may also make up the components of any given computer network. In addition, a Mobile Ad-Hoc Network (MANET) is a kind of wireless ad-hoc network, which is generally considered a self-configuring network of mobile routers (and associated hosts) connected by wireless links, the union of which forms an arbitrary topology.

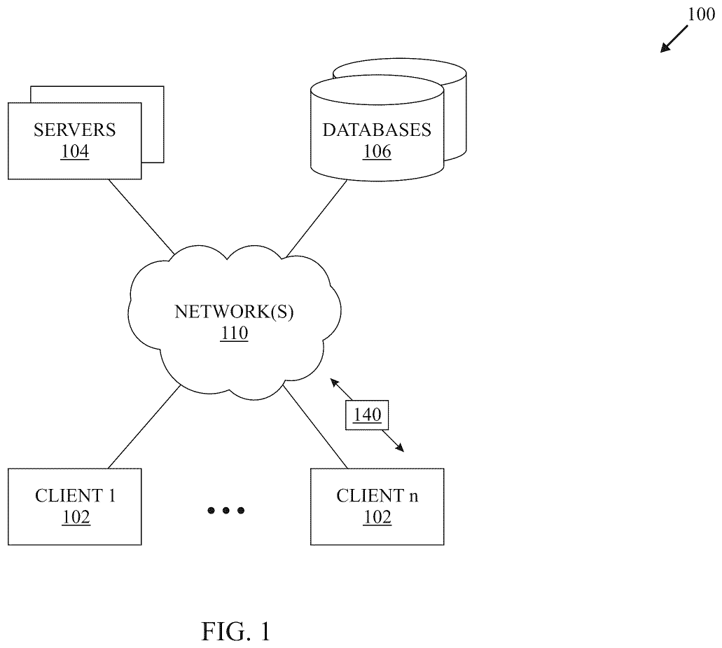

FIG. 1 is a schematic block diagram of an example simplified computing system (e.g., computing system 100) illustratively comprising any number of client devices (e.g., client devices 102 with, e.g., a first through nth client device), one or more servers (e.g., servers 104), and one or more databases (e.g., databases 106), where the devices may be in communication with one another via any number of networks (e.g., network(s) 110). The one or more networks (e.g., network(s) 110) may include, as would be appreciated, any number of specialized networking devices such as routers, switches, access points, etc., interconnected via wired and/or wireless connections. For example, devices 102-104 and/or the intermediary devices in network(s) 110 may communicate wirelessly via links based on WiFi, cellular, infrared, radio, near-field communication, satellite, or the like. Other such connections may use hardwired links, e.g., Ethernet, fiber optic, etc. The nodes/devices typically communicate over the network by exchanging discrete frames or packets of data (packets 140) according to predefined protocols, such as the Transmission Control Protocol/Internet Protocol (TCP/IP) other suitable data structures, protocols, and/or signals. In this context, a protocol consists of a set of rules defining how the nodes interact with each other.

Client devices 102 may include any number of user devices or end point devices configured to interface with the techniques herein. For example, client devices 102 may include, but are not limited to, desktop computers, laptop computers, tablet devices, smart phones, wearable devices (e.g., heads up devices, smart watches, etc.), set-top devices, smart televisions, Internet of Things (IoT) devices, autonomous devices, or any other form of computing device capable of participating with other devices via network(s) 110.

Notably, in some implementations, servers 104 and/or databases 106, including any number of other suitable devices (e.g., firewalls, gateways, and so on) may be part of a cloud-based service. In such cases, servers 104 and/or databases 106 may represent the cloud-based device(s) that provide certain services described herein, and may be distributed, localized (e.g., on the premise of an enterprise, or “on prem”), or any combination of suitable configurations, as will be understood in the art.

Those skilled in the art will also understand that any number of nodes, devices, links, etc. may be used in computing system 100, and that the view shown herein is for simplicity. Also, those skilled in the art will further understand that while the network is shown in a certain orientation, the computing system 100 is merely an example illustration that is not meant to limit the disclosure.

Notably, web services can be used to provide communications between electronic and/or computing devices over a network, such as the Internet. A web site is an example of a type of web service. A web site is typically a set of related web pages that can be served from a web domain. A web site can be hosted on a web server. A publicly accessible web site can generally be accessed via a network, such as the Internet. The publicly accessible collection of web sites is generally referred to as the World Wide Web (WWW).

Also, cloud computing generally refers to the use of computing resources (e.g., hardware and software) that are delivered as a service over a network (e.g., typically, the Internet). Cloud computing includes using remote services to provide a user's data, software, and computation.

Moreover, distributed applications can generally be delivered using cloud computing techniques. For example, distributed applications can be provided using a cloud computing model, in which users are provided access to application software and databases over a network. The cloud providers generally manage the infrastructure and platforms (e.g., servers/appliances) on which the applications are executed. Various types of distributed applications can be provided as a cloud service or as a Software as a Service (SaaS) over a network, such as the Internet.

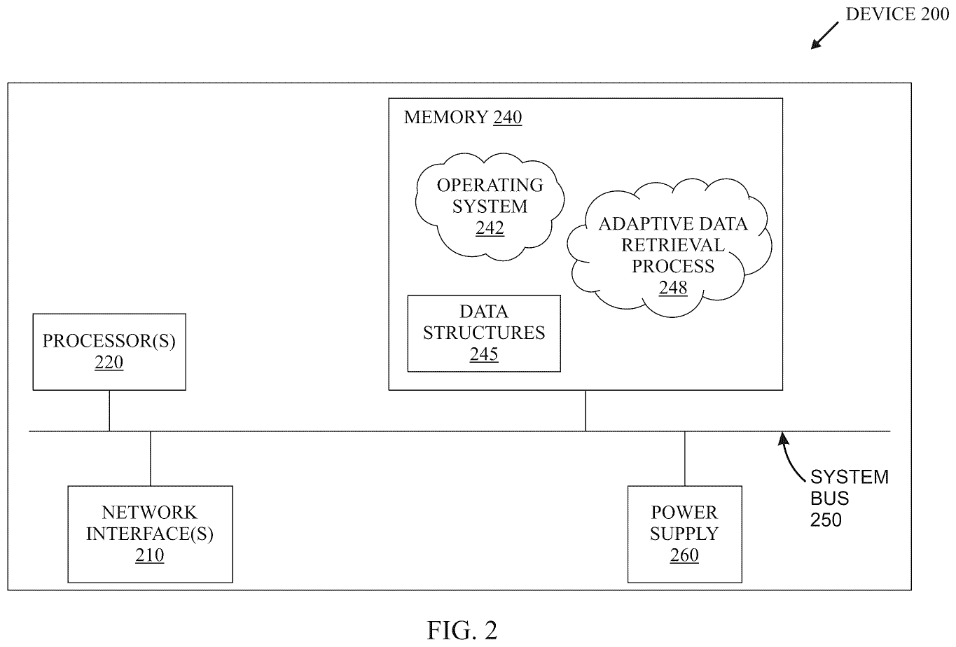

FIG. 2 is a schematic block diagram of an example node/device 200 (e.g., an apparatus) that may be used with one or more implementations described herein, e.g., as any of the nodes or devices shown in FIG. 1 above or described in further detail below. The device 200 may comprise one or more of the network interfaces 210 (e.g., wired, wireless, etc.), at least one processor (e.g., processor(s) 220), and a memory 240 interconnected by a system bus 250, as well as a power supply 260 (e.g., battery, plug-in, etc.).

The network interfaces 210 include the mechanical, electrical, and signaling circuitry for communicating data over physical links coupled to the computing system 100. The network interfaces may be configured to transmit and/or receive data using a variety of different communication protocols. Notably, a physical network interface (e.g., network interfaces 210) may also be used to implement one or more virtual network interfaces, such as for virtual private network (VPN) access, known to those skilled in the art.

The memory 240 comprises a plurality of storage locations that are addressable by the processor(s) 220 and the network interfaces 210 for storing software programs and data structures associated with the implementations described herein. The processor(s) 220 may comprise necessary elements or logic adapted to execute the software programs and manipulate the data structures 245. An operating system 242 (e.g., the Internetworking Operating System, or IOS®, of Cisco Systems, Inc., another operating system, etc.), portions of which are typically resident in memory 240 and executed by the processor(s), functionally organizes the node by, inter alia, invoking network operations in support of software processes and/or services executing on the device. These software processes and/or services may comprise one or more functional processes, and on certain devices, an adaptive data retrieval process 248, as described herein. Notably, the functional processes, when executed by processor(s) 220, may cause each device 200 to perform the various functions corresponding to the particular device's purpose and general configuration. For example, a router would be configured to operate as a router, a server would be configured to operate as a server, an access point (or gateway) would be configured to operate as an access point (or gateway), a client device would be configured to operate as a client device, and so on.

It will be apparent to those skilled in the art that other processor and memory types, including various computer-readable media, may be used to store and execute program instructions pertaining to the techniques described herein. Also, while the description illustrates various processes, it is expressly contemplated that various processes may be implemented as modules configured to operate in accordance with the techniques herein (e.g., according to the functionality of a similar process). Further, while processes may be shown and/or described separately, those skilled in the art will appreciate that processes may be routines or modules within other processes.

In various implementations, as detailed further below, adaptive data retrieval process 248 may include computer executable instructions that, when executed by processor(s) 220, cause device 200 to perform the techniques described herein. For example, adaptive data retrieval process 248 may include computer-executable instructions stored on a computer-readable medium that are executable by processor(s) 220 to cause node/device 200 to institute adaptive data retrieval technique using Agentic Prompt Processing Units (PPUs) as the ADR process. The techniques may be leveraged to create, assess, self-criticize, execute, and dynamically adapt complex plans, particularly, in scenarios requiring delegated data retrievals using service accounts where the number of functions that may be possibly called is large (e.g., in order of thousands or tens of thousands).

To do so, in some implementations, adaptive data retrieval process 248 may utilize machine learning. In general, machine learning is concerned with the design and the development of techniques that take as input empirical data (such as network statistics and performance indicators) and recognize complex patterns in these data. One very common pattern among machine learning techniques is the use of an underlying model M, whose parameters are optimized for minimizing the cost function associated to M, given the input data. For instance, in the context of classification, the model M may be a straight line that separates the data into two classes (e.g., labels) such that M=a*x+b*y+c and the cost function would be the number of misclassified points. The learning process then operates by adjusting the parameters a, b, c such that the number of misclassified points is minimal. After this optimization phase (or learning phase), model M can be used very easily to classify new data points. Often, M is a statistical model, and the cost function is inversely proportional to the likelihood of M, given the input data.

In various implementations, adaptive data retrieval process 248 may employ one or more supervised, unsupervised, or semi-supervised machine learning models. Generally, supervised learning entails the use of a training set of data, as noted above, that is used to train the model to apply labels to the input data. For example, the training data may include sample telemetry that has been labeled as being indicative of an acceptable performance or unacceptable performance. On the other end of the spectrum are unsupervised techniques that do not require a training set of labels. Notably, while a supervised learning model may look for previously seen patterns that have been labeled as such, an unsupervised model may instead look to whether there are sudden changes or patterns in the behavior of the metrics. Semi-supervised learning models take a middle ground approach that uses a greatly reduced set of labeled training data.

Example machine learning techniques that adaptive data retrieval process 248 can employ may include, but are not limited to, nearest neighbor (NN) techniques (e.g., k-NN models, replicator NN models, etc.), statistical techniques (e.g., Bayesian networks, etc.), clustering techniques (e.g., k-means, mean-shift, etc.), neural networks (e.g., reservoir networks, artificial neural networks, etc.), support vector machines (SVMs), long short-term memory (LSTM), logistic or other regression, Markov models or chains, principal component analysis (PCA) (e.g., for linear models), singular value decomposition (SVD), multi-layer perceptron (MLP) artificial neural networks (ANNs) (e.g., for non-linear models), replicating reservoir networks (e.g., for non-linear models, typically for timeseries), random forest classification, or the like.

In further implementations, adaptive data retrieval process 248 may also include one or more generative artificial intelligence/machine learning models. In contrast to discriminative models that simply seek to perform pattern matching for purposes such as data access controls, anomaly detection, classification, or the like, generative approaches instead seek to generate new content or other data (e.g., audio, video/images, text, etc.), based on an existing body of training data. For instance, in the context of prompt analysis, adaptive data retrieval process 248 may use a generative model to allow an Agentic PPU to create, assess, self-criticize, execute, and dynamically adapt complex plans, particularly, in scenarios requiring delegated data retrievals using service accounts where the number of functions that may be possibly called is large (e.g., in order of thousands or tens of thousands). Example generative approaches can include, but are not limited to, generative adversarial networks (GANs), foundation models such as large language models (LLMs), other transformer models, and the like.

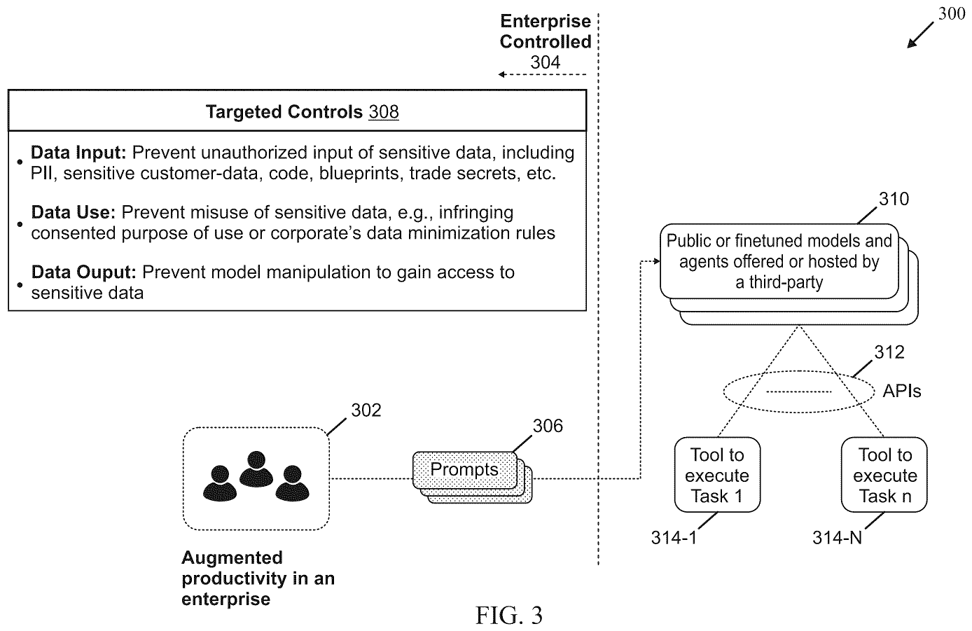

FIG. 3 illustrates an example of an architecture 300 for sending prompts to a remote language model, in accordance with one or more implementations described herein. In architecture 300, users 302 in an enterprise-controlled portion 304 (e.g., network) may send prompts 306 (e.g., queries, etc.) to an external machine learning model (e.g., machine learning model 310).

Typically, prompts 306 may be generated based on input directly from users 302, such as via a chatbot assistant. However, further implementations provide for the use of other programmatic approaches to generate prompts 306, such as by a user selecting a button within a user interface and the underlying program generating a prompt, or the like. In some instances, the executing program may send prompts 306 to machine learning model 310 via one or more application programming interfaces (APIs) and present the results to users 302, accordingly.

Machine learning model 310 may be a public or finetuned language model, such as an LLM, or any other generative AI model configured to process the prompts 306. For example, users 302 such as sales, marketing, customer support, data analytics, engineering, product management, or other personnel in the enterprise may utilize prompts 306 to enhance their productivity.

The increased use of generative AI is posing new challenges to enterprises with respect to data control. More specifically, enterprises need mechanisms that can prevent unauthorized input of sensitive data, the misuse of sensitive data, and/or model manipulation to gain access to sensitive data when utilizing generative AI. Indeed, sensitive data leakage and enterprise policy violations with generative AI are a key concern given that sensitive information may be referenced, used, and/or extracted indirectly (i.e., without explicitly being part of a query).

Further, sensitive information is often needed to complete a task, so personally identifiable information (PII) masking or redaction techniques may not work. In fact, in many cases, it is possible to use model-based analysis to detect the source even after masking or redacting PII. Furthermore, sensitive information may be misused (e.g., for a secondary purpose not compliant with consented purpose of use or by infringing Data Minimization Rules (DMRs)). For instance, specific enterprise controls are often not covered by masking filters and/or redaction techniques. It makes little sense to apply pattern matching controls, such as regular expressions (regex), Exact Data Matching (EDM), or Indexed Document Matching (IDM) techniques to next generation natural language-based systems.

Although many enterprises aim to leverage generative AI, they may also want to observe what tasks are requested by prompts 306 for performance by machine learning model 310. Additionally, users may want to observe and control what data is sent, used, and returned by these third-party systems. Consequently, while the prompts 306, users 302, and any corresponding API calls that they may make may be within the enterprise-controlled portion 304.

During processing of any of prompts 306, machine learning model 310 may itself leverage one or more APIs 312 to interact with a set of tools 314 (e.g., a first tool 314-1 through nth tool 314-n) to perform any number of discrete tasks. For instance, the set of tools 314 may allow machine learning model 310 to retrieve information from a certain source, as part of its processing. More complex approaches also provide for the set of tools 314 allowing machine learning model 310 to exert some control over an underlying system or device.

Also as shown, from the perspective of the enterprise, there may be a set of targeted controls 308 that the enterprise desires, such as any or all of the following:
Data input—e.g., preventing the unauthorized input of sensitive data, including PII, customer data, code, blueprints, trade secrets, etc.
Data use—e.g., prevent misuse of sensitive data, such as infringing a consented purpose of use or the data minimization rules of the entity
Data output—e.g., preventing manipulation of machine learning model 310 to gain access to the sensitive data

While many online machine learning models (e.g., ChatGPT, etc.) today are able to interpret open-ended prompts and act upon them by generating artifacts based on such understanding, this skill is also not accessible to the enterprise itself. This lack of skill hinders the ability to effectively implement all of the additional controls (e.g., set of targeted controls 308) listed above on the data, before prompts 306 are sent to an external entity from that of the enterprise.

### Data Controls Using Prompt Processing Units

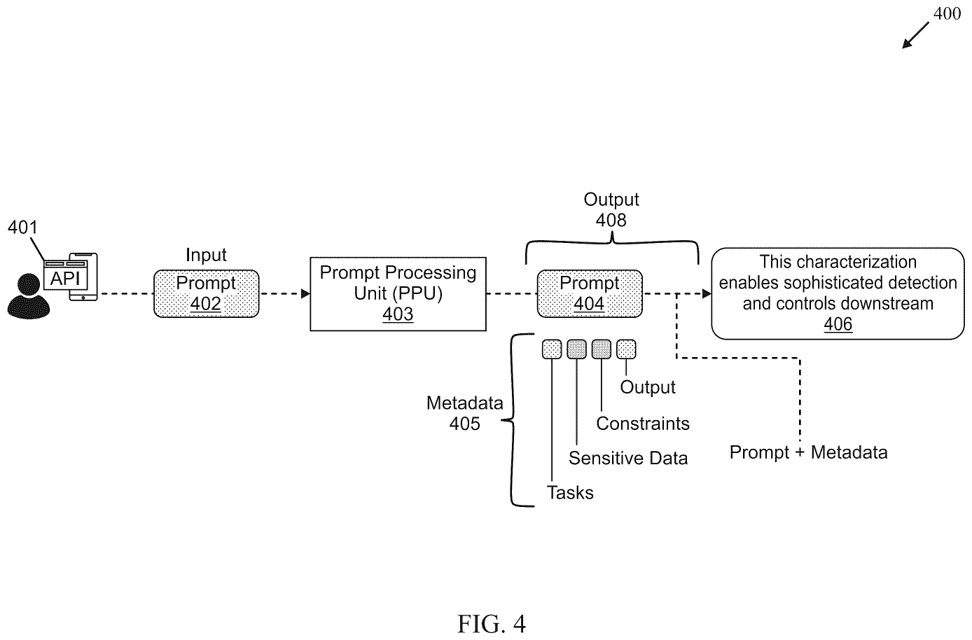

FIG. 4 illustrates an example of an architecture 400 for utilizing PPUs, according to various implementations. In some instances, architecture 400 may be a portion of a data control system that leverages the outputs of PPUs to institute downstream data controls.

As shown, architecture 400 includes a prompt processing unit (PPU 403). A PPU 403 may be a highly efficient processing element that may receive a prompt 402 as an input (e.g., from a user chat interface or an API 401). PPU 403 may parse the query and/or may detect a set of key features from the query carried in a prompt at inference time.

For instance, PPU 403 may detect key features within the prompt 402. These may include the class of tasks requested to an LLM (e.g., “Coding Support”), additional details about the class of tasks detected (e.g., “create a python program”), the data needed to complete the tasks (e.g., a snippet of python code), any constraints applicable to carry out the tasks (e.g., “use the code snippet provided”, or “stick to NumPy”), the desired output upon completion of such tasks (e.g., “stdout”), etc.

A PPU 403 may act as a transparent element, delivering the unmodified prompt 404 augmented with metadata 405 carrying the key features, such as those described above. More specifically, a PPU 403 may systematically distill and characterize prompts, allowing for downstream controls 406 to be applied.

As noted above, the recent breakthroughs in large language models (LLMs) represent new opportunities across a wide spectrum of industries. More specifically, the ability of new models to follow instructions now allow for interactions with tools that are able to perform tasks such as searching the web, executing code, etc. In addition, agents can be developed to perform complex tasks and workflows by chaining multiple calls to one or more LLMs.

For instance, a human user or a headless client agent may generate a prompt, where the completion of such prompt by one or more LLMs requires the use of data stored in one or more enterprise data sources (e.g., Splunk, ThousandEyes, and enterprise databases). Another headless agent, such as an Agentic Data Retrieval (ADR) process may receive the prompt, either by working in tandem with the one or more LLMs or by being placed on the path toward the one or more LLMs.

However, leveraging an ADR process is not without challenges. Even if an ADR process could correctly identify the data required by a prompt and map such information to a set of candidate functions to be called in order to retrieve the data, there are still several problems that need to be solved before a prompt can be successfully completed.

For instance, the same data might be stored in multiple systems, often with varying levels of quality and complexity to retrieve the desired data. Moreover, once a plan is defined, the mere nature of an ADR process implies that its execution is not deterministic. In addition, attempts to retrieve data may fail (e.g., the data might not be available anymore, or the permissions and/or entitlements of a user, a group of users, or a service account associated to a retrieval function might have changed). Consequently, once a plan is defined, its execution is not guaranteed and may need to be adapted dynamically.

Today, generating answers to questions involving distributed data sources remains a manual process not suited to automation and/or LLM intervention due to these challenges and others. Instead, these operations are performed by experts or with the help of experts having knowledge in appropriate data sources.

Other approaches have included the use of retrieval augmented generation (RAG) techniques, where some enterprise data might be vectorized and available via RAG solutions. However, even companies that use RAG techniques typically won't “RAGify” all their data due to several concerns including: data duplication issues in brownfield environments; maintenance effort and cost; the challenges associated with adding RAG in scenarios subject to medium/high data dynamicity and varying relevance depending on data freshness; the technical limitations of state-of-the-art RAG techniques themselves (for instance: a) selecting the optimal search and re-ranking algorithm to prioritize the most relevant documents is not trivial; b) integrating identity, access management, and data from different identity providers is a challenge, etc.); etc.

### Adaptive Data Retrieval Using Agentic Processing Unit

In contrast, the techniques described herein address these challenges through an adaptive data retrieval technique using Agentic Prompt Processing Units (PPUs) as the ADR process. The techniques allow an Agentic PPU to create, assess, self-criticize, execute, and dynamically adapt complex plans, particularly, in scenarios requiring delegated data retrievals using service accounts where the number of functions that may be possibly called is large (e.g., in order of thousands or tens of thousands).

Illustratively, the techniques described herein may be performed by hardware, software, and/or firmware, such as in accordance with adaptive data retrieval process 248, which may include computer executable instructions executed by the processor(s) 220 (or independent processor of the network interfaces 210) to perform functions relating to the techniques described herein.

Specifically, according to various implementations, a device obtains a request for a generative artificial intelligence-based system to perform a task. The device formulates a primary data retrieval plan comprising a set of one or more data retrievers that the generative artificial intelligence-based system is to use to perform a task. The device identifies an issue experienced by the generative artificial intelligence-based system when performing the task in accordance with the primary data retrieval plan. The device causes, based on the issue, the generative artificial intelligence-based system to switch to an alternative data retrieval plan comprising a different set of one or more data retrievers.

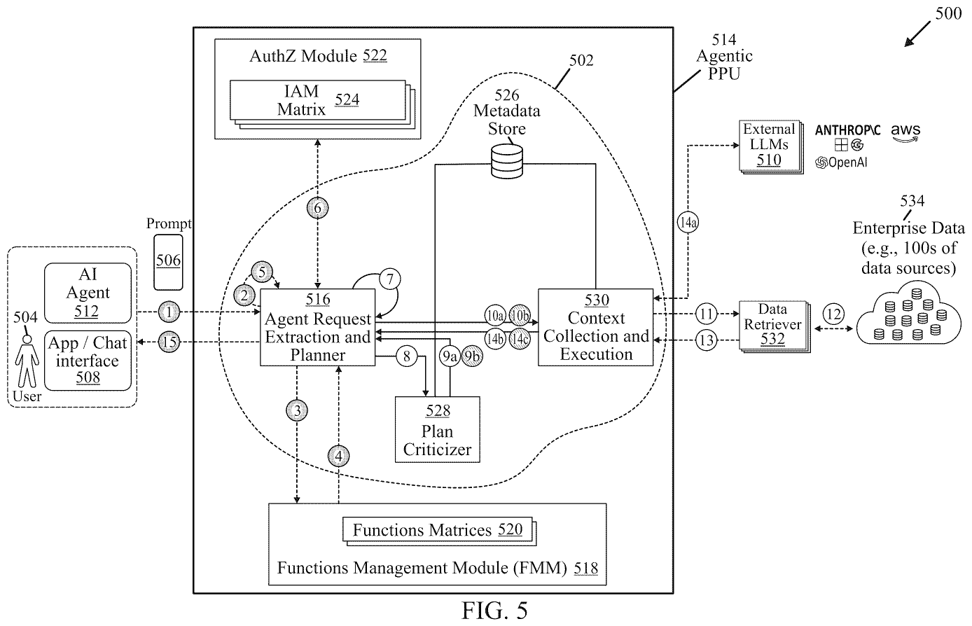

Operationally, FIG. 5 illustrates an example of an architecture 500 implementing a system 502 targeted towards adaptive data retrieval technique using Agentic Prompt Processing Units (PPUs). The system 502 may herein facilitate an Agentic PPU in creating, assessing, self-criticizing, executing, and dynamically adapting complex plans, including automated mechanisms to:
a) Identify the one or more enterprise data sources and data records required to complete a prompt, if any.
b) Map the enterprise data identified to a set of candidate functions capable of retrieving the requested data.
c) Perform AuthZ lookups, resolve, and identify the specific service accounts, functions, and data retrievers to be called.
d) Search for previous plans that were successfully executed to complete the same type of request carried in a prompt. For instance, requests that were subject to equivalent input arguments and expected outcome. More specifically, the following prompt: “Create a report listing all the leads during Q1 for which we didn't have follow-up meetings”, may not be automatized as a recurrent report generated each quarter, but still, if a user makes a new request, such as the following: “Generate a report showing the leads we had during Q3 that are pending a follow-up meeting”, the plans required to complete the requests are fundamentally the same, the difference lies mainly in the input arguments.
e) Select from an existing plan in a catalog or create a new one.
f) Assess and self-criticize the plan identified.
g) Modify or adopt the plan.
h) Execute the plan selected, dynamically assess its execution, and adapt if needed.
i) Parametrize, index, and catalog the plans that were successfully executed.

For instance, a user 504 may utilize an application or chat interface 508 to generate a prompt 506 to be processed and completed by one of more Large Language Models (LLMs) (e.g., external LLMs 510). Prompt 506 may also be generated by a headless client, e.g., AI agent 512.

A prompt 506 generated either by user 504 or the AI agent 512 may reach or be intercepted by the agentic PPU 514. More specifically, prompts (e.g., prompt 506) may be either intercepted or received by agentic PPU 514, which might be reachable as part of a SaaS deployment provisioned by a solution provider, or it might be deployed on premise as part of the company's infrastructure. For instance, some enterprises have developed multiple ways to intercept and transparently create copies of the prompt 506, including plugins for Cisco WebEx, Slack, Kong, python SDKs providing wrappers around widely used libraries, including OpenAI, Azure OpenAI and Langchain, as well as npm libraries for React.

In various implementations, adaptive data retrievals may be implemented using agentic Prompt Processing Units (PPUs) such as by a set of steps one through fifteen. For example, in a first step, the prompt 506 generated by the user 504 and/or the AI agent 512 may reach or be intercepted by agentic request extraction and planner 516, which may include the client-facing element within the agentic PPU 514.

In step two, the agentic request extraction and planner 516 may parse the prompt received and determine whether a plan needs to be created. In various implementations, agentic request extraction and planner 516 may detect that the prompt payload received does not require access to enterprise data sources 534, and therefore, the creation and execution of a plan to retrieve enterprise data is not needed.

In such a case, agentic request extraction and planner 516 may instruct other elements within agentic PPU 514 to skip the steps three to thirteen and proceed directly to step (14a). For instance, this may be the case for prompt requests such as the following: “What does pip install do?” or “Translate the following text . . . ”.

However, if agentic request extraction and planner 516 infers in step two that enterprise data is required to complete a request carried in prompt 506, it may issue a lookup request in step three, to one or more functions matrices (e.g., functions matrices 520), which might be part of a Functions Management Module (FMM) (e.g., FMM 518).

To this end, agentic request extraction and planner 516 may leverage and utilize automated data to function mapping using agentic prompt processing units”. For instance, the lookup process performed in step three may result in the identification of a set of plausible functions and their corresponding attributes in step four, as potential candidates to be called to retrieve the data requested in prompt 506.

This set of candidate functions may be used as an input to one or more specialized xLLMs that may be part of the agentic request extraction and planner 516, where these may comprise and/or combine models of various sizes, including small, medium, or large language models. More specifically, specialized xLLMs may be queried in step five, in order to determine which specific functions should be called among the candidates identified. Furthermore, the identification and generation of a reduced set of plausible functions may also be supported by the one or more specialized xLLMs, or by other models within FMM 518.

In step six, the set of functions {f} identified in step five along with the requestor's identity may be used by agentic request extraction and planner 516 as an input to AuthZ module 522. The AuthZ request generated by agentic request extraction and planner 516 may leverage and utilize delegated data retrieval using agentic prompt processing units. For instance, AuthZ module 522 may embed one or more IAM matrices (e.g., IAM Matrix 524).

Upon receiving an AuthZ request from Agentic Request Extraction and Planner 516, AuthZ module 522 may provide means to verify the authenticity and validity of the access token received. This may entail querying the company's IdP and/or AuthZ server, which may also use or be linked to one or more Active Directory servers.

In various implementations, this may entail token introspection techniques, especially, for opaque tokens. Once the identity is verified and validated, AuthZ module 522 may perform a lookup process in the one or more IAM matrices (e.g., IAM Matrix 524). If the result of the lookup process determines that, at least one of the data retrievals requested in prompt 506 is denied (e.g., when one of the functions in the set {f} cannot be rightfully executed), then AuthZ module 522 may inform agentic request extraction and planner 516 of such denial, which in turn may inform the requestor.

If on the contrary, all the data requested is authorized (e.g., when all the functions in the set {f} can be rightfully executed), then AuthZ module 522 may inform agentic request extraction and planner 516 that the AuthZ was granted, which in turn may proceed to step seven.

In step seven, upon receiving an AuthZ OK in step six, agentic request extraction and planner 516 may first search for an existing plan in a catalog of plans within metadata store 526. If a previous plan that meets the requested data retrieval is found, then agentic request extraction and planner 516 may select such plan.

If instead, a plan is not found, then agentic request extraction and planner 516 may create a primary plan as well as one or more alternative plans comprising a list of ordered steps to sequentially invoke and execute the corresponding set of functions {f} identified and rely on a set of service accounts (e.g., identified in step six), which may be required for the data retrievals.

Steps eight and nine may be performed next. For instance, agentic request extraction and planner 516 may then present prompt 506, along with the primary plan and the one or more alternative plans created to a plan criticizer 528 in step eight. The latter may embed one or more specialized language models (e.g., fine-tuned models from pre-trained LLMs), which may be trained to assess and criticize an array of plans for a given prompt, both of which might be received by plan criticizer 528 as an input. More specifically:
Agentic request extraction and planner 516 may have been trained with a loss that penalizes when its predicted Primary Plan (P_A) differs from a plan that is “equivalent” to the Ground-Truth Plan (GTP), and therefore, the plan created by agentic request extraction and planner 516 for calling the functions {f} and retrieve the requested data is either incorrect or suboptimal. The term “equivalent” herein, may denote the fact that the plans created to complete the requested data retrieval may correctly deliver the same data, even though the number of steps and their order may vary across the plans.
Instead, plan criticizer 528 might have been trained on a different data set than agentic request extraction and planner 516, which may cascade the plans P_A generated by agentic request extraction and planner 516 as an input, with a loss that penalizes when the predicted plan P_B, for performing the requested data retrievals created by plan criticizer 528, is such that P_B differs from a plan that is “equivalent” to GTP, when P_A is not equivalent to GTP. In case the primary plan P_A is equivalent to plan P_B, plan criticizer 528 may communicate to agentic request extraction and planner 516 that it agrees with primary plan P_A in step (9a). Otherwise, it may iterate by processing and assessing the rest of the alternative plans received in the array.

In case, a first alternative plan P_A′ is found to be equivalent to plan P_B, plan criticizer 528 may communicate to agentic request extraction and planner 516 that it agrees with alternative plan P_A′. Instead, if after iterating over all the alternative plans in the array, plan criticizer 528 couldn't find one that works, it may request the agentic request extraction and planner 516 to replan and repeat step seven, eight, and nine, or cancel and exit. In an alternative embodiment, agentic request extraction and planner 516 may only produce and send a single primary plan to plan criticizer 528, i.e., no alternative plans may be generated in step seven.

In contrast to automated data to function mapping using agentic prompt processing units, where the plans may require verification and confirmation from users and/or client agents before their execution, the techniques introduced herein may target self-assessment and self-criticism capabilities using plan criticizer 528, including dynamic replanning in non-deterministic environments. Indeed, the separation of concerns and complementarity among a planner (e.g., agentic request extraction and planner 516), a criticizer (e.g., plan criticizer 528), and an executor (e.g., context collection and execution 530) may facilitate the creation and automation of sophisticated plans in an autonomous way (i.e., without requiring verification and confirmation from a user and/or a client agent).

In step ten, the primary plan identified may be passed to context collection and execution 530 for its execution. Then, in step eleven, context collection and execution 530 may begin executing the plan defined by agentic request extraction and planner 516 in steps seven, eight, and (9a), by invoking a first specialized data retriever (e.g., data retriever 532) (e.g., embodied as a lambda function with a data connector and a runtime, or as yet another agent). Such a data retriever may be able to use the service accounts identified as a result of the lookup performed in step six. Then, in step twelve a first data retriever (e.g., data retriever 532) may now get the corresponding data from the various enterprise data sources (e.g., enterprise data sources 534), as determined by the one or more functions identified in the set {f}.

Then steps thirteen to fifteen may be performed. For example, the data obtained by a first data retriever (e.g., data retriever 532) may be sent back to context collection and execution 530 in step thirteen. Context collection and execution 530 may then observe the state of the execution of the plan received and sequentially invoke a next specialized (e.g., data retriever 532) from the set of data retriever IDs authorized in step six. Context collection and execution 530 may repeat steps eleven, twelve, and thirteen as many times as needed, to cover the various data retrievers identified and complete the execution of the plan received in step (10a).

In some cases, the execution of the initial plan may fail (e.g., some steps may not be completed, some data might not be retrieved due to a connectivity failure, or an excessive delay in the response of a function call, etc.). In such cases, context collection and execution 530 may indicate this to the agentic request extraction and planner 516 in step (14c).

Agentic request extraction and planner 516 may be endowed with mechanisms to dynamically adapt and replan, leading in this case to new steps seven, eight, (9b), (10b) as well as possible iterations on steps eleven, twelve, and thirteen. Once the data retrievals are completed and the plan is correctly executed, context collection and execution 530 may request one or more LLMs (e.g., external LLMs 510), in step (14a), to compile and prepare a final response to the original requestor (e.g., user 504 or AI agent 512). The final response may be forwarded to the agentic request extraction and planner 516, which in turn may now send the prompt completion to the corresponding requestor in step fifteen.

The set of plans that were successfully executed and completed may be stored in metadata store 526. To this end, successful plans may be parametrized and cataloged, so they can be reused later on.

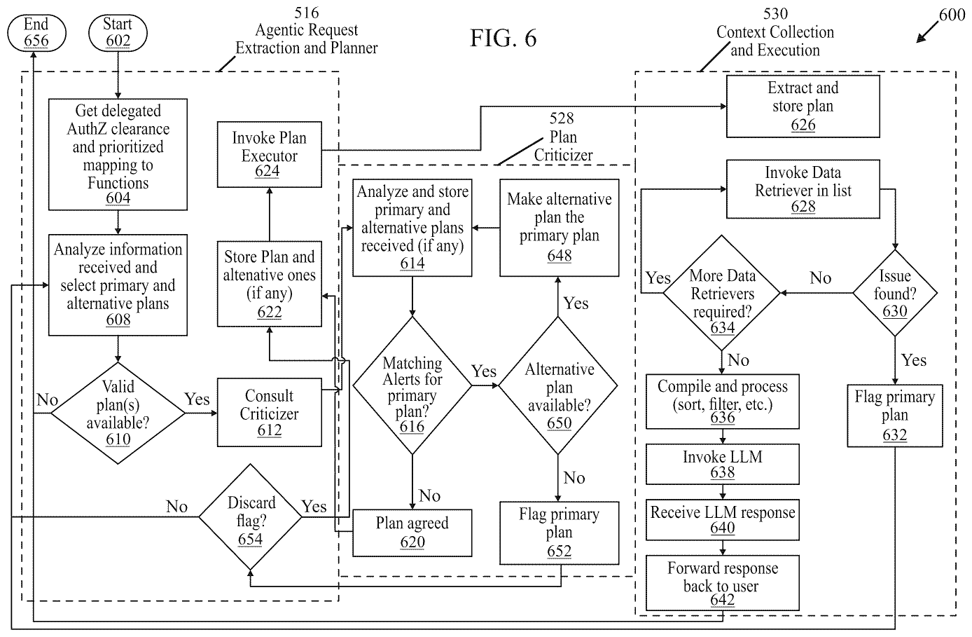

FIG. 6 illustrates an example of a simplified procedure incorporating some of the main interactions between agentic request extraction and planner 516, plan criticizer 528, and/or context collection and execution 530. Procedure 600 may start at step 602 and proceed through the depicted set of processes to end at step 656.

For example, at step 604 delegated AuthZ clearance and/or prioritized mapping to functions may be obtained. At step 608 information received may be analyzed and primary and/or alternative plans may be selected. At step 610, a determination may be made whether valid plans are available. If they are not, then the procedure 600 may proceed to end at step 656.

Conversely, if there is a valid plan available, then the procedure 600 may proceed to consult the criticizer at step 612. The plan criticizer 528 may analyze and store primary and alternative plans received if any at step 614. Then, a determination may be made at step 616 whether there are any matching alerts for a primary plan. If not, then the plan is agreed at step 620 and the plan and/or any alternative ones may be stored at step 622 and the plan executor may be invoked in step 624. There, the plan may be extracted and stored at step 626 and the corresponding data retriever may be invoked in the list at step 628. A determination may be made at step 630 whether an issue is found. If an issue is found, then the primary plan may be flagged at step 632 and the procedure may proceed back to step 608.

If at step 630 a determination is made that there are no issues found, then a determination may be made at step 634 whether more data retrievers are required. If so, then the procedure 600 may proceed back to step 628. If not, then procedure 600 may proceed to compile and process (e.g., sort, filter, etc.) at step 636, invoke an LLM at step 638, receive an LLM response at step 640, and/or forward the response back to the user at step 642. The procedure 600 may then end at step 656.

Returning to the determination whether a step 616 whether there are any matching alerts for a primary plan, if there are then a determination may be made whether an alternative plan is available 650. If there is, then the alternative plan may be made the primary plan at step 648 and the procedure 600 may return to step 614. If there is not, then the primary plan may be flagged at step 652 and a determination may be made by the agentic request extraction and planner 516 whether the flag should be discarded at step 654. If the determination is that it should be discarded, then the procedure 600 may return to step 622. If the determination is that it should not be discarded, then the procedure 600 may return to step 608.

It should be noted that while certain steps within the procedure 600 and/or the set of steps for adaptive data retrievals may be implemented using agentic PPUs, etc., and may be optional as described above, the steps shown are merely examples for illustration, and certain other steps may be included or excluded as desired. Further, while a particular order of the steps is shown, this ordering is merely illustrative, and any suitable arrangement of the steps may be utilized without departing from the scope of the implementations herein.

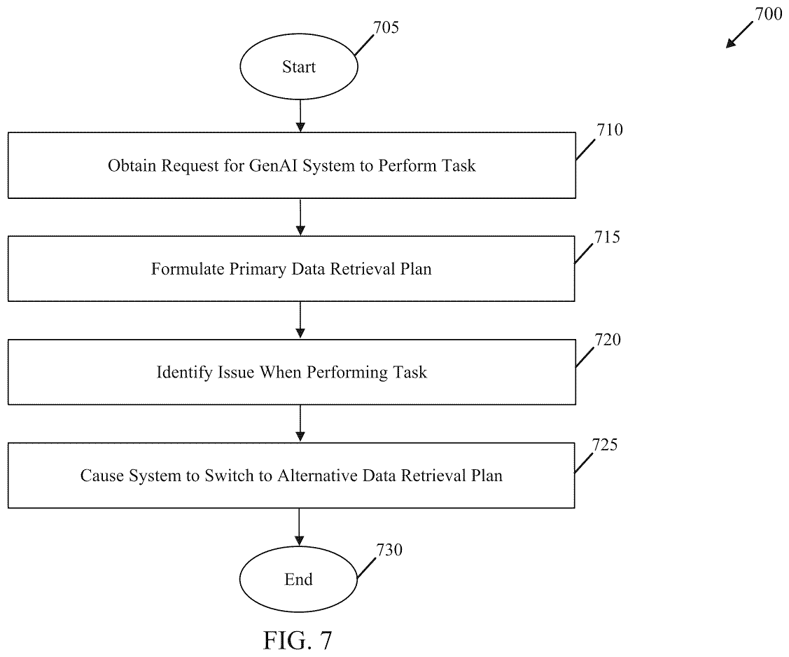

FIG. 7 illustrates an example of a simplified procedure for using prompt processing units for adaptive data retrieval, in accordance with one or more implementations described herein. For example, a non-generic, specifically configured device (e.g., device 200), may perform procedure 700 (e.g., a method) by executing stored instructions (e.g., adaptive data retrieval process 248). The procedure 700 may start at step 705, and continues to step 710, where, as described in greater detail above, the device (e.g., a controller, processor, etc.) may obtain a request for a generative artificial intelligence-based system to perform a task. In one implementation, the generative artificial intelligence-based system comprises one or more artificial intelligence agents.

At step 715, as detailed above, the device may formulate a primary data retrieval plan comprising a set of one or more data retrievers that the generative artificial intelligence-based system is to use to perform a task. In various implementations, the device formulates the primary data retrieval plan based in part on an access token associated with the request. In some implementations, the set of one or more data retrievers comprise a function call to retrieve a particular type of data needed by the generative artificial intelligence-based system to complete the task.

At step 720, the device may identify an issue experienced by the generative artificial intelligence-based system when performing the task in accordance with the primary data retrieval plan, as described in greater detail above. In various implementations, the device may also formulate the alternative data retrieval plan, prior to identifying the issue. In such cases, the device may further perform critical analysis of the primary data retrieval plan and the alternative data retrieval plan, to designate the primary data retrieval plan for use first by the generative artificial intelligence-based system. In one instance, the issue corresponds to a type of data no longer being available from a particular data source. In a further instance, the issue corresponds to a lack of authorization to access a type of data from a particular data source.

At step 725, as detailed above, the device may cause, based on the issue, the generative artificial intelligence-based system to switch to an alternative data retrieval plan comprising a different set of one or more data retrievers. In various implementations, the generative artificial intelligence-based system uses one or more large language models to perform the task. In one implementation, the device may also store the alternative data retrieval plan for processing future requests.

Procedure 700 then ends at step 730.

It should be noted that while certain steps within procedure 700 may be optional as described above, the steps shown are merely examples for illustration, and certain other steps may be included or excluded as desired. Further, while a particular order of the steps is shown, this ordering is merely illustrative, and any suitable arrangement of the steps may be utilized without departing from the scope of the implementations herein.

The techniques described herein, therefore, introduce adaptive data retrieval technique using Agentic Prompt Processing Units (PPUs) as the ADR process. The techniques allow an Agentic PPU to create, assess, self-criticize, execute, and dynamically adapt complex plans, particularly, in scenarios requiring delegated data retrievals using service accounts where the number of functions that may be possibly called is large (e.g., in order of thousands or tens of thousands).

While there have been shown and described illustrative implementations that provide for intelligent caching of structured document analyses, it is to be understood that various other adaptations and modifications may be made within the intent and scope of the implementations herein. In addition, while certain processes are shown, other suitable processes may be used, accordingly.

The foregoing description has been directed to specific implementations. It will be apparent, however, that other variations and modifications may be made to the described implementations, with the attainment of some or all of their advantages. For instance, it is expressly contemplated that the components and/or elements described herein can be implemented as software being stored on a tangible (non-transitory) computer-readable medium (e.g., disks/CDs/RAM/EEPROM/etc.) having program instructions executing on a computer, hardware, firmware, or a combination thereof. Accordingly, this description is to be taken only by way of example and not to otherwise limit the scope of the implementations herein. Therefore, it is the object of the appended claims to cover all such variations and modifications as come within the true spirit and scope of the implementations herein.

What is claimed is:

1. A method, comprising:
obtaining, by a device, a request for a generative artificial intelligence-based system to perform a task;
formulating, by the device, a primary data retrieval plan comprising a set of one or more data retrievers that the generative artificial intelligence-based system is to use to perform a task;
identifying, by the device, an issue experienced by the generative artificial intelligence-based system when performing the task in accordance with the primary data retrieval plan; and
causing, by the device and based on the issue, the generative artificial intelligence-based system to switch to an alternative data retrieval plan comprising a different set of one or more data retrievers.

2. The method as in claim 1, wherein the generative artificial intelligence-based system uses one or more large language models to perform the task.

3. The method as in claim 1, further comprising:
formulating, by the device, the alternative data retrieval plan, prior to identifying the issue.

4. The method as in claim 3, further comprising:
performing, by the device, critical analysis of the primary data retrieval plan and the alternative data retrieval plan, to designate the primary data retrieval plan for use first by the generative artificial intelligence-based system.

5. The method as in claim 1, wherein the device formulates the primary data retrieval plan based in part on an access token associated with the request.

6. The method as in claim 1, wherein the set of one or more data retrievers comprise a function call to retrieve a particular type of data needed by the generative artificial intelligence-based system to complete the task.

7. The method as in claim 1, wherein the issue corresponds to a type of data no longer being available from a particular data source.

8. The method as in claim 1, wherein the issue corresponds to a lack of authorization to access a type of data from a particular data source.

9. The method as in claim 1, wherein the generative artificial intelligence-based system comprises one or more artificial intelligence agents.

10. The method as in claim 1, further comprising:
storing, by the device, the alternative data retrieval plan for processing future requests.

11. An apparatus, comprising:
one or more network interfaces;
a processor coupled to the one or more network interfaces and configured to execute one or more processes; and
a memory configured to store a process that is executable by the processor, the process when executed configured to:
obtain a request for a generative artificial intelligence-based system to perform a task;
formulate a primary data retrieval plan comprising a set of one or more data retrievers that the generative artificial intelligence-based system is to use to perform a task;
identify an issue experienced by the generative artificial intelligence-based system when performing the task in accordance with the primary data retrieval plan; and
cause, based on the issue, the generative artificial intelligence-based system to switch to an alternative data retrieval plan comprising a different set of one or more data retrievers.

12. The apparatus as in claim 11, wherein the generative artificial intelligence-based system uses one or more large language models to perform the task.

13. The apparatus as in claim 12, wherein the process when executed is further configured to:
formulate the alternative data retrieval plan, prior to identifying the issue.

14. The apparatus as in claim 13, wherein the process when executed is further configured to:
perform critical analysis of the primary data retrieval plan and the alternative data retrieval plan, to designate the primary data retrieval plan for use first by the generative artificial intelligence-based system.

15. The apparatus as in claim 11, wherein the apparatus formulates the primary data retrieval plan based in part on an access token associated with the request.

16. The apparatus as in claim 11, wherein the set of one or more data retrievers comprise a function call to retrieve a particular type of data needed by the generative artificial intelligence-based system to complete the task.

17. The apparatus as in claim 11, wherein the issue corresponds to a type of data no longer being available from a particular data source.

18. The apparatus as in claim 11, wherein the issue corresponds to a lack of authorization to access a type of data from a particular data source.

19. The apparatus as in claim 11, wherein the generative artificial intelligence-based system comprises one or more artificial intelligence agents.

20. A tangible, non-transitory, computer-readable medium storing program instructions that cause a device to execute a process comprising:
obtaining, by the device, a request for a generative artificial intelligence-based system to perform a task;
formulating, by the device, a primary data retrieval plan comprising a set of one or more data retrievers that the generative artificial intelligence-based system is to use to perform a task;
identifying, by the device, an issue experienced by the generative artificial intelligence-based system when performing the task in accordance with the primary data retrieval plan; and
causing, by the device and based on the issue, the generative artificial intelligence-based system to switch to an alternative data retrieval plan comprising a different set of one or more data retrievers.
